(19) United States
(12) Patent Application Publication
(10) Pub. No.: US 2017/0343619 A1
(43) Pub. Date: Nov. 30, 2017

(54) TWO-STAGE OPTICAL DNV EXCITATION

(71) Applicant: Lockheed Martin Corporation, Bethesda, MD (US)

(72) Inventors: Arul Manickam, Mount Laurel, NJ (US); Peter G. Kaup, Marlton, NJ (US); Gregory Scott Bruce, Abington, PA (US); Wilbur Lew, Mount Laurel, NJ (US)

(73) Assignee: Lockheed Martin Corporation, Bethesda, MD (US)

(21) Appl. No.: 15/382,045

(22) Filed: Dec. 16, 2016

Related U.S. Application Data
(60) Provisional application No. 62/343,600, filed on May 31, 2016.

(51) Int. Cl. G01R 33/032

(52) U.S. Cl. CPC G01R 33/032

(57) ABSTRACT

A system for magnetic detection includes a magneto-optical defect center material comprising a plurality of magneto-optical defect centers, a radio frequency (RF) excitation source, an optical detector, and an optical light source. The RF excitation source is configured to provide RF excitation to the material. The optical detector is configured to receive an optical signal emitted by the material. The optical light source includes a readout optical light source configured to provide optical excitation to the material to transition relevant magneto-optical defect center electrons to excited spin states in the material, and a reset optical light source configured to provide optical light to the material to reset spin states in the material to a ground state. The reset optical light source provides a higher power light than the readout optical light source.

### CROSS-REFERENCE TO RELATED PATENT APPLICATION

The present application claims the benefit of priority from U.S. Provisional Patent Application No. 62/343,600, filed May 31, 2016, which is incorporated herein by reference in its entirety.

This application is related to U.S. Patent Provisional Application No. 62/343,602, filed May 31, 2016, entitled “SELECTED VOLUME CONTINUOUS ILLUMINATION MAGNETOMETER”, attorney docket no. 111423-1143, the entire contents of which are incorporated by reference herein in its entirety.

### FIELD

The present disclosure generally relates to magnetic detection systems, and more particularly, to measurement and signal processing methods for a magnetic detection system.

### BACKGROUND

Many advanced magnetic imaging systems can operate in limited conditions, for example, high vacuum and/or cryogenic temperatures, which can make them inapplicable for imaging applications that require ambient conditions. Small size, weight and power (SWAP) magnetic sensors of moderate sensitivity, vector accuracy, and bandwidth are valuable in many applications.

Atomic-sized nitrogen-vacancy (NV) centers in diamond have excellent sensitivity for magnetic field measurement and enable fabrication of small magnetic sensors that can readily replace existing-technology (e.g., Hall-effect) systems and devices. The sensing capabilities of diamond NV (DNV) sensors are maintained at room temperature and atmospheric pressure, and these sensors can be even used in liquid environments (e.g., for biological imaging). DNV sensing allows measurement of 3-D vector magnetic fields that is beneficial across a very broad range of applications.

### SUMMARY

According to certain embodiments, a system for magnetic detection may include: a magneto-optical defect center material comprising a plurality of magneto-optical defect centers; a radio frequency (RF) excitation source configured to provide RF excitation to the magneto-optical defect center material; an optical detector configured to receive an optical signal emitted by the magneto-optical defect center material; and an optical light source. The optical light source includes: a readout optical light source configured to provide optical excitation to the magneto-optical defect center material to transition relevant magneto-optical defect center electrons to excited spin states in the magneto-optical defect center material; and a reset optical light source configured to provide optical light to the magneto-optical defect center material to reset spin states in the magneto-optical defect center material to a ground state, wherein the reset optical light source provides a higher power light than the readout optical light source.

According to certain embodiments the readout optical light source is a laser and the reset optical light source is a bank of LED flash-bulbs.

According to certain embodiments the readout optical light source is an LED and the reset optical light source is a bank of LED flash-bulbs.

According to certain embodiments the readout optical light source has a higher duty cycle than the reset optical light source.

According to certain embodiments a method for magnetic detection, comprises: irradiating a magneto-optical defect center material comprising a plurality of magneto-optical defect centers with radio frequency (RF) excitation; irradiating the magneto-optical defect center material with optical excitation from a readout optical light source to transition relevant magneto-optical defect center electrons to excited spin states in the magneto-optical defect center material; detecting an optical signal from the magneto-optical defect center material based on the magneto-optical defect center material being irradiated with optical excitation; and irradiating the magneto-optical defect center material with optical light from a reset optical light source to reset spin states in the magneto-optical defect center material to a ground state after irradiating the magneto-optical defect center material with optical excitation, wherein the reset optical light source provides a higher power light than the readout optical light source.

According to certain embodiments, a system for magnetic detection, comprising: a magneto-optical defect center material comprising a plurality of magneto-optical defect center centers; a radio frequency (RF) excitation source configured to provide RF excitation to the magneto-optical defect center material; an optical detector configured to receive an optical signal emitted by the magneto-optical defect center material; and an optical light source configured to provide optical light to the magneto-optical defect center material, the optical light source comprising: a readout optical light source configured to illuminate light in a first illumination volume of the magneto-optical defect center material; and a reset optical light source configured to illuminate light in a second illumination volume of the magneto-optical defect center material, the second illumination volume being larger than and encompassing the first illumination volume.

According to certain embodiments the readout optical light source is a laser and the reset optical light source is a bank of LED flash-bulbs. According to certain embodiments, the readout optical light source is an LED and the reset optical light source is a bank of LED flash-bulbs. According to certain embodiments the readout optical light source has a higher duty cycle than the reset optical light source.

### BRIEF DESCRIPTION OF THE DRAWINGS

FIG. 1 illustrates one orientation of an NV center in a diamond lattice.

FIG. 2 illustrates an energy level diagram showing energy levels of spin states for the NV center.

FIG. 3 illustrates a schematic diagram of a NV center magnetic sensor system.

FIG. 4 illustrates a graph of the fluorescence as a function of an applied RF frequency of an NV center along a given direction for a zero magnetic field, and also for a non-zero magnetic field having a component along the NV axis.

FIG. 5 illustrates a graph of the fluorescence as a function of an applied RF frequency for four different NV center orientations for a non-zero magnetic field.

FIG. 6 is a schematic diagram illustrating a magnetic field detection system according to some embodiments.

FIG. 7 is a schematic illustrating details of the optical light source of the magnetic field detection system of FIG. 6 according to some embodiments.

FIG. 8 illustrates the illumination volume in NV diamond material for a readout optical light source and a reset optical light source of the optical light source of the magnetic field detection system of FIG. 6 according to an embodiment.

FIG. 9 illustrates a RF sequence according to some embodiments.

FIG. 10 is a magnetometry curve in the case of a continuous optical excitation RF pulse sequence according to some embodiments.

FIG. 11 is a magnetometry curve in the case of a continuous optical excitation RF pulse sequence where the waveform has been optimized for collection intervals according to some embodiments.

FIG. 12 is magnetometry curve for the left most resonance frequency of FIG. 11 according to some embodiments.

FIG. 13 is a graph illustrating the dimmed luminescence intensity as a function of time for the region of maximum slope of FIG. 12.

FIG. 14 is a graph illustrating the normalized intensity of the luminescence as a function of time for diamond NV material for a continuous optical illumination of the diamond NV material in a RF sequence measurement.

FIG. 15 is a graph of a zoomed in region of FIG. 14.

### DETAILED DESCRIPTION

### The NV Center, its Electronic Structure, and Optical and RF Interaction

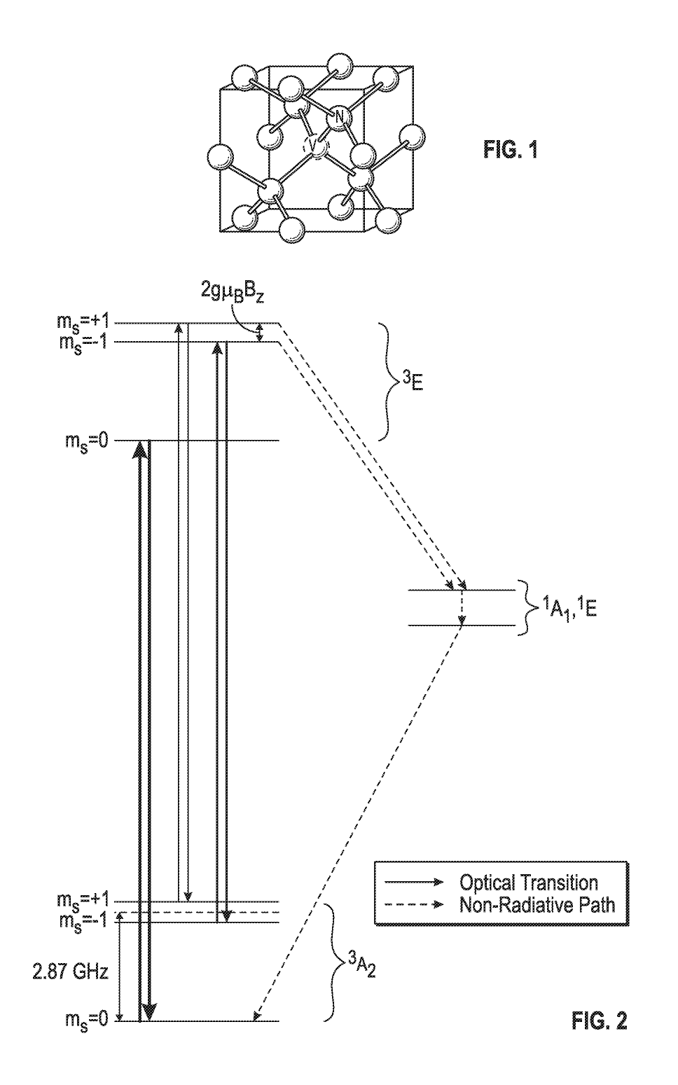

The NV center in a diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. Conventionally, the neutral charge state uses the nomenclature NV⁰, while the negative charge state uses the nomenclature NV⁻ or, more generally, NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2gμ_{B}Bz, where g is the electron g-factor, μ_{B} is the Bohr magneton, and Bz is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

### The NV Center, or Magneto-Optical Defect Center, Magnetic Sensor System

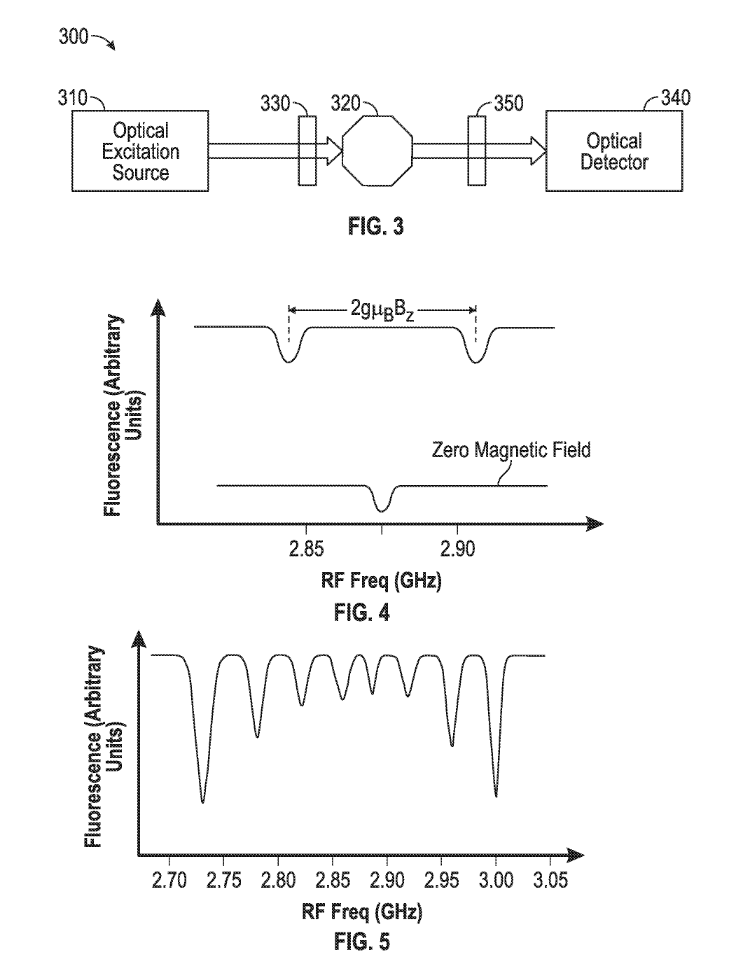

FIG. 3 is a schematic diagram illustrating a conventional NV center magnetic sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 is directed through the optical filter 350 to filter out light in the excitation band (in the green, for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples of pulsed excitation schemes include RF pulse sequence (described in more detail below), and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results, along with the known orientation of crystallographic planes of a diamond lattice, allow not only the magnitude of the external magnetic field to be determined, but also the direction of the magnetic field.

While FIG. 3 illustrates an NV center magnetic sensor system 300 with NV diamond material 320 with a plurality of NV centers, in general, the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

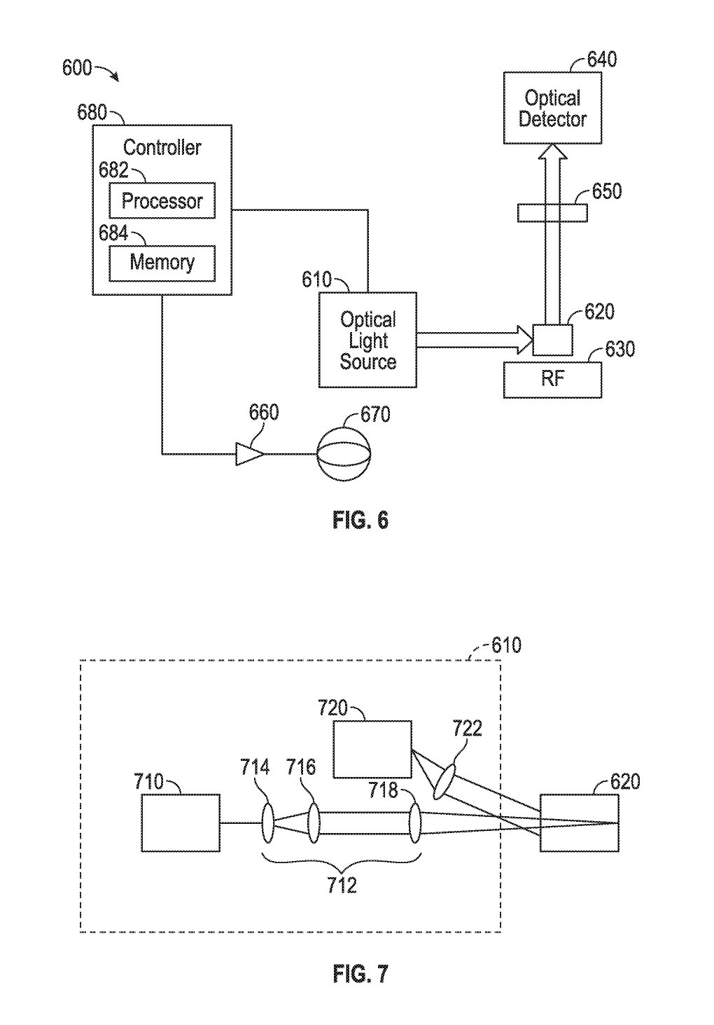

FIG. 6 is a schematic diagram of a system 600 for a magnetic field detection system according to some embodiments.

The system 600 includes an optical light source 610, which directs optical light to an NV diamond material 620 with NV centers, or another magneto-optical defect center material with magneto-optical defect centers. An RF excitation source 630 provides RF radiation to the NV diamond material 620. The system 600 may include a magnetic field generator 670 which generates a magnetic field, which may be detected at the NV diamond material 620, or the magnetic field generator 670 may be external to the system 600. The magnetic field generator 670 may provide a biasing magnetic field.

The system 600 further includes a controller 680 arranged to receive a light detection signal from the optical detector 640 and to control the optical light source 610, the RF excitation source 630, and the magnetic field generator 670. The controller may be a single controller, or multiple controllers. For a controller including multiple controllers, each of the controllers may perform different functions, such as controlling different components of the system 600. The magnetic field generator 670 may be controlled by the controller 680 via an amplifier 660, for example.

The RF excitation source 630 may include a microwave coil or coils, for example. The RF excitation source 630 may be controlled to emit RF radiation with a photon energy resonant with the transition energy between the ground mₛ=0 spin state and the mₛ=±1 spin states as discussed above with respect to FIG. 3, or to emit RF radiation at other nonresonant photon energies.

The controller 680 is arranged to receive a light detection signal from the optical detector 640 and to control the optical light source 610, the RF excitation source 630, and the magnetic field generator 670. The controller 680 may include a processor 682 and a memory 684, in order to control the operation of the optical light source 610, the RF excitation source 630, and the magnetic field generator 670. The memory 684, which may include a nontransitory computer readable medium, may store instructions to allow the operation of the optical light source 610, the RF excitation source 630, and the magnetic field generator 670 to be controlled. That is, the controller 680 may be programmed to provide control.

### Reset and Read Out Optical Light Sources

FIG. 7 is a schematic illustrating details of the optical light source 610. The optical light source 610 may include a readout optical light source 710 and reset optical light source 720. The readout optical light source 710 may be a laser or a light emitting diode, for example, which emits light in the green, for example. The readout optical light source 710 induces fluorescence in the red from the NV diamond material 620, where the fluorescence corresponds to an electronic transition of the NV electron pair from the excited state to the ground state. Referring back to FIG. 6, light from the NV diamond material 620 is directed through the optical filter 650 to filter out light in the excitation band (in the green, for example), and to pass light in the red fluorescence band, which in turn is detected by the optical detector 640. Thus, the readout optical light source 710 induces fluorescence which is then detected by the optical detector 640, i.e., the fluorescence induced by the readout optical light source 710 is read out.

The reset optical light source 720 of the optical light source 610 serves to reset the population of the mₛ=0 spin state of the ground state ³A₂ to a maximum polarization, or other desired polarization. In general, it may be desired in a reset stage to reset the spin population to the desired spin state relatively quickly to reduce the reset time, and thus to increase sensor bandwidth. In this case the reset optical light source 720 provides light of a relatively high power. Further, the reset optical light source 720 may have a lower duty cycle than readout optical light source 710, thus providing reduced heating of the system.

On the other hand, a relatively lower power may be desired for the readout optical light source 710 to provide a higher accuracy readout. The relatively lower power readout optical light source 710 beneficially allows for easier control of the spectral purity, a slower readout time with lower noise, reduced laser heating, and may be light weight and compact. Thus, the reset optical light source 720 may provide light of a higher power than that of the readout optical light source 710. The readout optical light source 710 does provide some amount of a reset function. However, a lower powered light source takes longer to provide a reset and thus is tolerable.

Thus, the higher powered reset optical light source 720 provides advantages such as decreasing the time required for reset. Moreover, the higher powered reset optical light source 720 clears the previous polarization of the spin states of the NV centers. This may be important particularly in the case where the previous polarization is at another frequency pertaining to a different NV center crystallographic orientation. This is applicable to both pulse excitation schemes such as RF pulse sequence or spin-echo pulse sequence, as well as for continuous wave excitation where the RF field is scanned during the continuous wave excitation. For example, for continuous wave excitation where the RF field is scanned, the reset optical light source 720 may reduce the time required to jump between Lorentzians, and clears out prior residual RF information, for, for example, vector magnetometry or thermally compensated scalar magnetometry. This reduction of time allows for better vector estimation and/or increased sampling bandwidth. Thus the benefits of a higher power reset optical light source of lower duty cycle, wider beamwidth, and stronger power apply to either pulsed or continuous wave applications.

This combination of two optical light sources, one with a relatively high power to provide reset of the spin polarization and another to induce fluorescence for the readout provides a system with shorter reset times, while at the same time providing a high accuracy readout. The ratio of the power of the reset optical light source 720 to the readout optical light source 710 may be 10 to 1 or 20 to 1, or greater, for example.

Further the two optical light source magnetometer systems described herein improve the efficiency of the magnetometer by allowing for sensitive optical collection to be performed over a longer period using a low light density, low noise, light source while maintaining reasonable repolarization and reset times with a higher power light source when measurements are not critical. These two optical light source magnetometer systems allow for optimization of sensitivity via full excitation power versus collection integration time trade space, and further improves SWaP-C (size, weight, power and cost) design space by tailoring excitation source performance to specific needs.

The readout optical light source 710 may be a laser or an LED, for example, while the reset optical light source 720 may a laser, or an LED. Exemplary arrangements are as follows. The readout optical light source 710 may be a lower powered laser, and the reset optical light source 720 may be a higher powered laser with a lower duty cycle. The readout optical light source 710 may be a lower powered laser, and the reset optical light source 720 may be a bank of LED flash-bulbs. The readout optical light source 710 may be an LED, and the reset optical light source 720 may be a bank of LED flash-bulbs.

### Reset and Read Out Illumination Volumes

Referring to FIG. 7, the optical light source 610 may include a focusing lens 722 to focus light from the reset optical light source 720 onto the NV diamond material 620. Similarly, the optical light source 610 may include focusing optics 712 to focus light from the readout optical light source 710 onto the NV diamond material 620. For example, the focusing optics 712 may include lenses 714, 716, and 718.

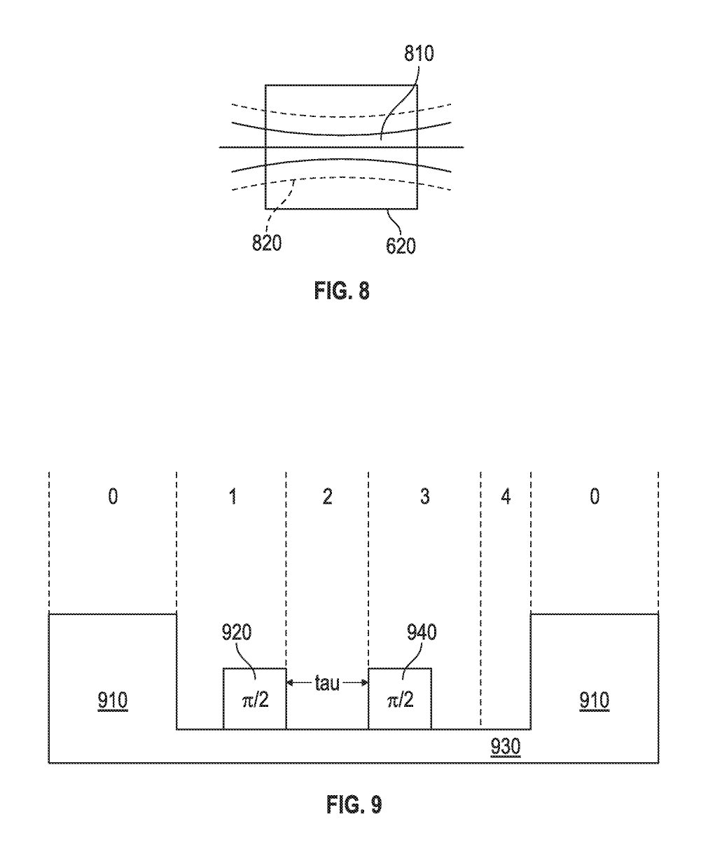

FIG. 8 illustrates the illumination volume 810 of the light beam from the readout optical light source 710 and the illumination volume 820 of the light beam from the reset optical light source 720 in the diamond material 620. The illumination volume 810 is shown between solid lines in FIG. 8, while the illumination volume 820 is shown between the dashed lines. The focusing optics 712 reduces the size of the illumination volume 810 of the diamond material 620 which is illuminated with the excitation beam from the readout optical light source 710. In general, the illumination volume depends on the spot size of the focused light beam in the diamond material 620. By reducing the illumination volume 810 in the diamond material 620, a higher light density for a given readout optical light source 710 power is achieved, and further magnetic bias field inhomogeneities and RF field variations over the optically excited region of the diamond material can be reduced.

On the other hand, the illumination volume 820 of the diamond material 620 which is illuminated by the reset optical light source 720 does not need to be as small as that for the readout optical light source 710. The illumination volume 820 of the diamond material 620 which is illuminated by the reset optical light source 720 should encompass the illumination volume 810 of the diamond material 620 which is illuminated by the readout optical light source 710. In this way the reset optical light source 720 will act to reset the NV spin states in the region of the diamond material 620 which will be illuminated with the readout optical light source 710.

### Continuous Wave/RF Pulse Sequence Example

The present system may be used for continuous optical excitation, or pulsed excitation, such as modified Ramsey pulse sequence, modified Hahn-Echo, or modified spin echo pulse sequence. This section describes an exemplary continuous wave/pulse (cw-pulse) sequence. According to certain embodiments, the controller 680 controls the operation of the optical light source 610, the RF excitation source 630, and the magnetic field generator 670 to perform Optically Detected Magnetic Resonance (ODMR). The component of the magnetic field Bz along the NV axis of NV centers aligned along directions of the four different orientation classes of the NV centers may be determined by ODMR, for example, by using an ODMR pulse sequence according to a pulse sequence. The pulse sequence is a pulsed RF scheme that measures the free precession of the magnetic moment in the NV diamond material 620 and is a technique that quantum mechanically prepares and samples the electron spin state.

FIG. 9 is a timing diagram illustrating the continuous wave/pulse sequence. As shown in FIG. 9, a cw-pulse sequence includes optical excitation pulses and RF excitation pulses over a five-step period. In a first step, during a period 0, a first optical reset pulse 910 from the reset optical light source 720 is applied to the system to optically pump electrons into the ground state (i.e., mₛ=0 spin state). This is followed by a first RF excitation pulse 920 (in the form of, for example, a microwave (MW) π/2 pulse), provided by the RF excitation source 630, during a period 1. The first RF excitation pulse 920 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and accumulate phase) over a time period referred to as tau (τ). Next, a second RF excitation pulse 940 (in the form of, for example, a MW π/2 pulse) is applied during a period 3 to project the system back to the mₛ=0 and mₛ=+1 basis. During period 4 which corresponds to readout, optical light 930 is provided by the readout optical light source 710, to optically sample the system and a measurement basis is obtained by detecting the fluorescence intensity of the system. The optical light 930 may be provided as an optical pulse, or as discussed further below, in a continuous manner throughout periods 0 through 4. Finally, the first optical reset pulse 910 from the reset optical light source 720 is applied again to begin another cycle of the cw-pulse sequence.

When the first optical reset pulse 910 is applied again to reset to the ground state at the beginning of another sequence, the readout stage is ended. The cw-pulse sequence shown in FIG. 9 may be performed multiple times, wherein each of the MW pulses applied to the system during a given cw-pulse sequence includes a different frequency over a frequency range that includes RF frequencies corresponds to different NV center orientations. The magnetic field may be then be determined based on the readout values of the fluorescence change correlated to unknown magnetic fields.

### Low Power Continuous Optical Excitation for RF Pulse Sequence

Referring back to FIG. 9, the optical light 930 is provided by the readout optical light source 710 in a continuous optical excitation manner. This provides a number of advantages over systems which turn on and off the light source providing light for optical readout during a RF sequence. Such systems which turn on and off the light source are susceptible to jitter noise interfering with the RF excitation source, and address this issue by increasing the laser light path length using optics so as to not be close to the RF excitation source, or by including a digital current source for the laser, for example.

By operating the readout optical light source 710 in a continuous optical excitation manner, the system provides a number of advantages. The system does not need extra components such as an acousto-optic modulator (AOM), or a digital current source. Further, optics, such as mirrors and lenses, are not needed to increase the path length of the laser light path. Thus, the system may be less expensive. Still further, there is no need to synchronize turning on and off the light from readout optical light source 710 with the RF excitation source, since the readout optical light source 710 remains continuously on during the RF pulse sequence.

For the continuous optical excitation for RF pulse sequence, the readout optical light source 710 is continuously on during the sequence, and thus continuously performs some amount of reset to the ground state throughout the sequence. Since the readout optical light source 710 provides a relatively low power beam, however, the reset is tolerable.

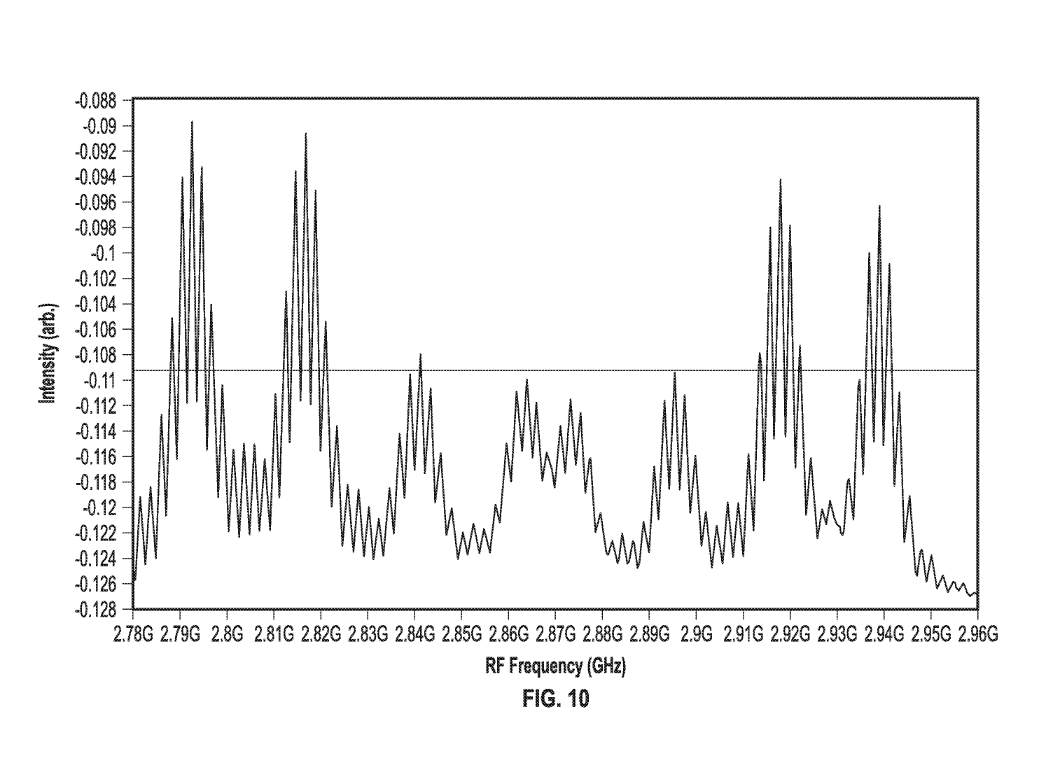

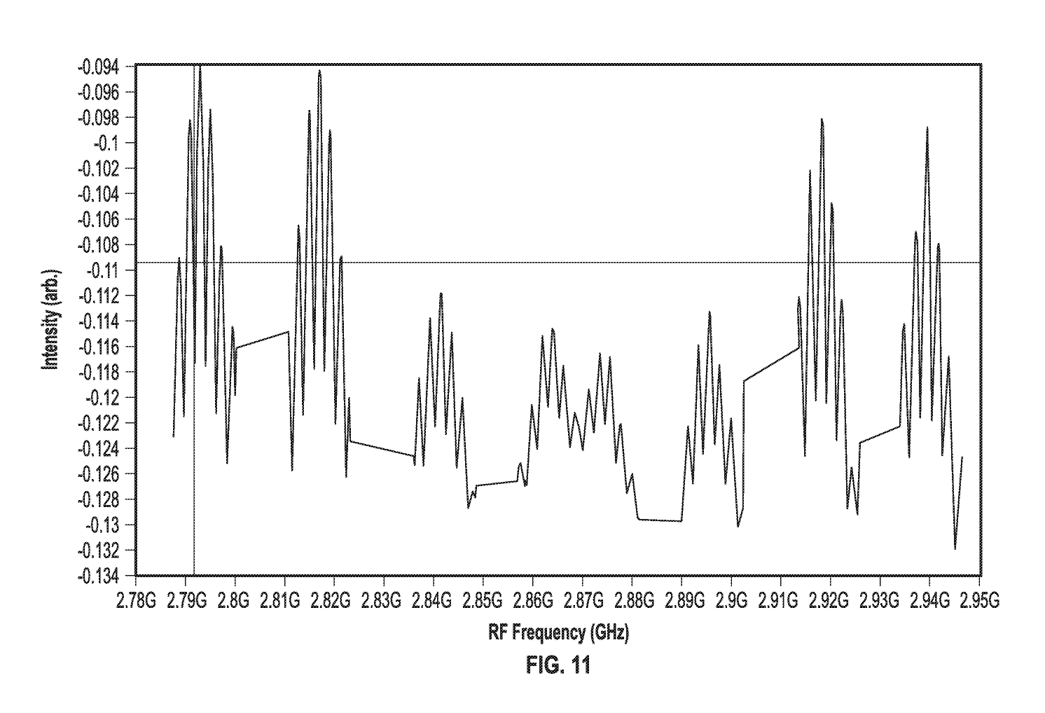

FIG. 10 illustrates a magnetometry curve in the case of using a continuous optical excitation RF pulse sequence. FIG. 10 shows the dimmed luminescence intensity at readout as a function of RF frequency applied during the RF pulse sequences. As can be seen, there are 8 spin state transition envelopes, each having a respective resonance frequency, for the case where the diamond material has NV centers aligned along directions of four different orientation classes. This is similar to the 8 spin state transitions shown in FIG. 5 for continuous wave optical excitation where the RF frequency is scanned. The magnetic field component along each of the four different orientation classes can be determined in a similar manner to that in FIG. 5. FIG. 11 illustrates a magnetometry curve similar to that of FIG. 10, where the RF waveform, including τ, has been optimized for each ˜12.5 MHz collection interval.

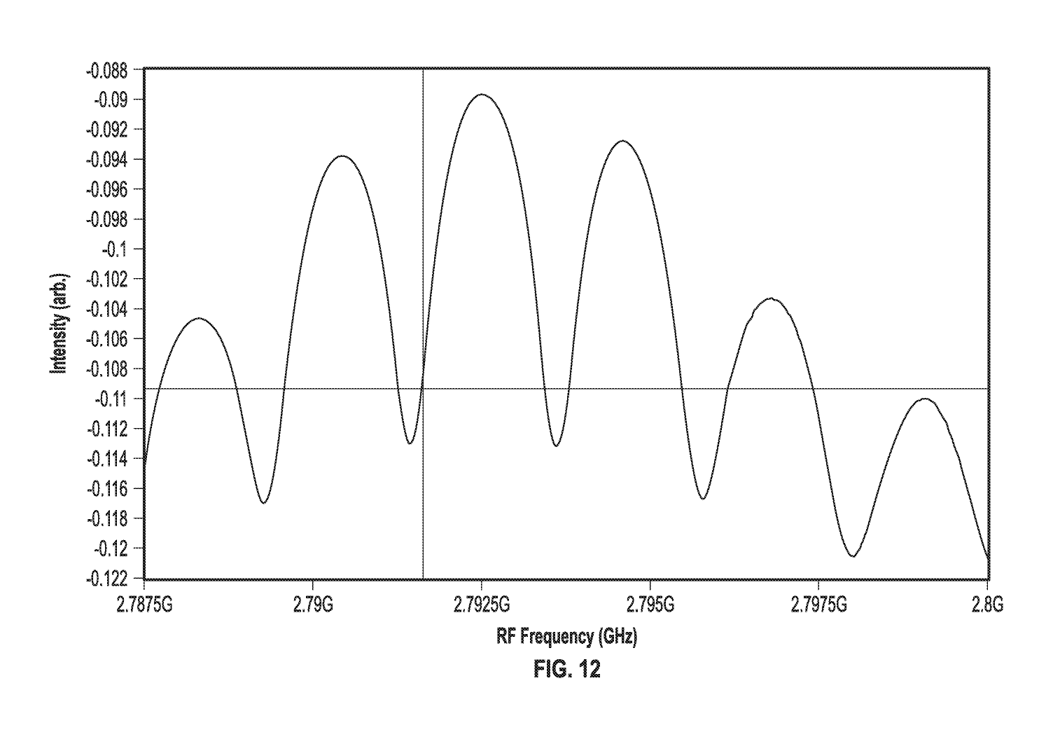

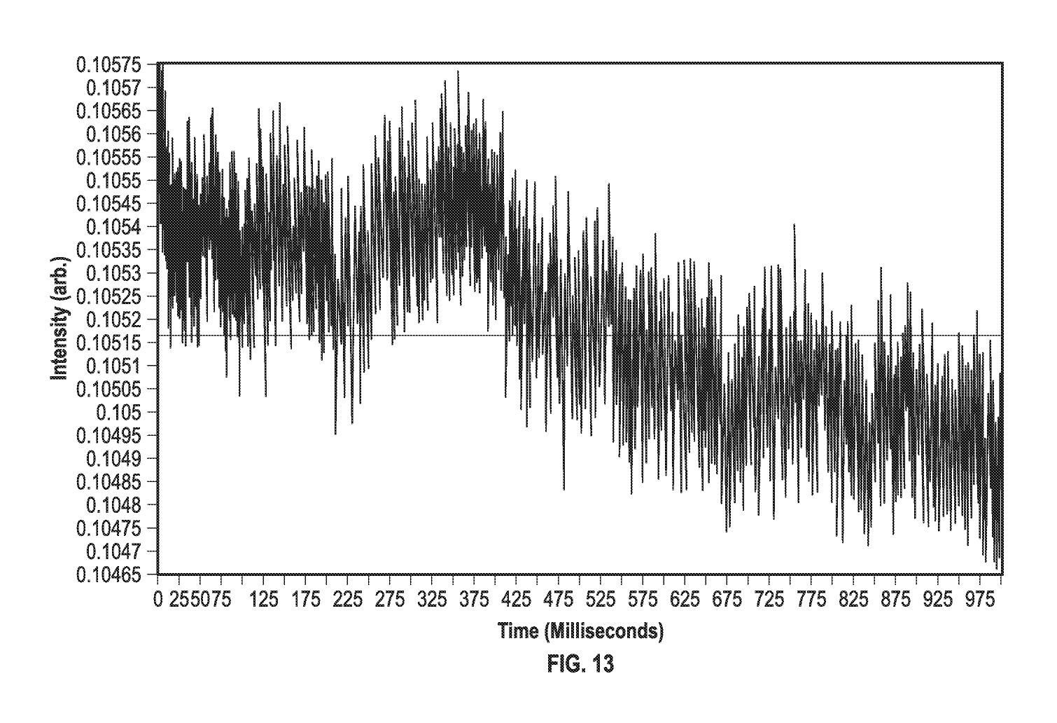

FIG. 12 illustrates a magnetometry curve for the left most resonance frequency of FIG. 11. In monitoring the magnetic field, the dimmed luminescence intensity, i.e., the amount the fluorescence intensity diminishes from the case where the spin states have been set to the ground state, of the region having the maximum slope may be monitored. If the dimmed luminescence intensity does not change with time, the magnetic field component does not change. A change in time of the dimmed luminescence intensity indicates that the magnetic field is changing in time, and the magnetic field may be determined as a function of time. For example, FIG. 13 illustrates the dimmed luminescence intensity as a function of time for the region of the maximum slope of FIG. 12.

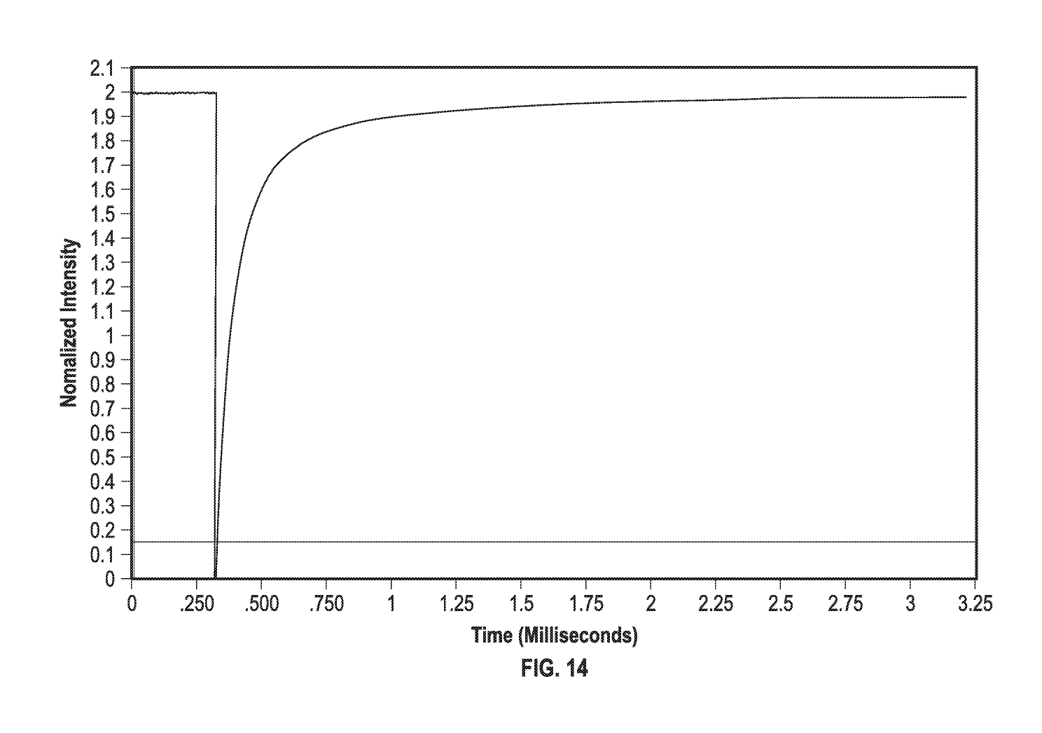

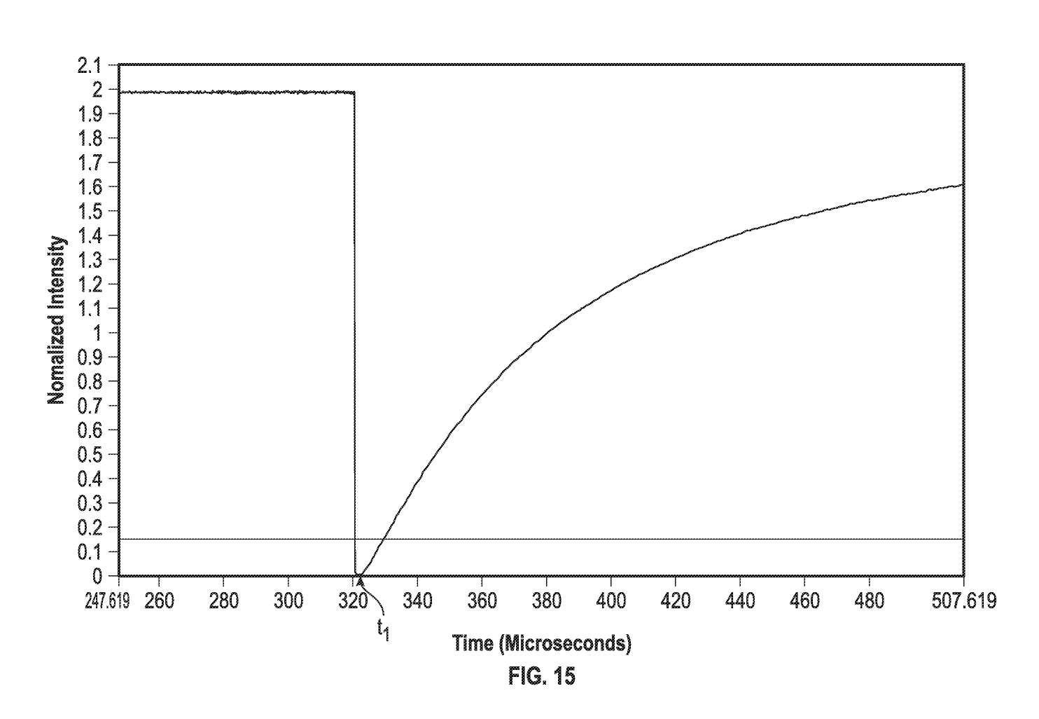

FIG. 14 illustrates the normalized intensity of the luminescence as a function of time for diamond NV material for a continuous optical illumination of the diamond NV material during a time which includes application of RF excitation according to a RF pulse sequence. Initially, the NV centers have all been reset to the ground state and the normalized intensity has a maximum value. At a time t1, RF excitation according to a RF sequence is applied and the normalized polarization drops to a minimum value. The normalized intensity continues to increase after t1 as the ground state population continues to increase. FIG. 15 illustrates a zoomed in region of FIG. 14 including time t1. The intensity may be read out for a time starting after t1 and integrated. The time at which the read out stops and high power reset begins may be set based on the application.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A system for magnetic detection, comprising:
a magneto-optical defect center material comprising a plurality of magneto-optical defect centers;
a radio frequency (RF) excitation source configured to provide RF excitation to the magneto-optical defect center material;
an optical detector configured to receive an optical signal emitted by the magneto-optical defect center material; and
an optical light source comprising:
a readout optical light source configured to provide optical excitation to the magneto-optical defect center material to transition relevant magneto-optical defect center electrons to excited spin states in the magneto-optical defect center material; and
a reset optical light source configured to provide optical light to the magneto-optical defect center material to reset spin states in the magneto-optical defect center material to a ground state,
wherein the reset optical light source provides a higher power light than the readout optical light source.

2. The system of claim 1, wherein the readout optical light source is a laser and the reset optical light source is a bank of LED flash-bulbs.

3. The system of claim 1, wherein the readout optical light source is an LED and the reset optical light source is a bank of LED flash-bulbs.

4. The system of claim 1, wherein the readout optical light source has a higher duty cycle than the reset optical light source.

5. A method for magnetic detection, comprising:
irradiating a magneto-optical defect center material comprising a plurality of magneto-optical defect centers with radio frequency (RF) excitation;
irradiating the magneto-optical defect center material with optical excitation from a readout optical light source to transition relevant magneto-optical defect center electrons to excited spin states in the magneto-optical defect center material;
detecting an optical signal from the magneto-optical defect center material based on the magneto-optical defect center material being irradiated with optical excitation; and
irradiating the magneto-optical defect center material with optical light from a reset optical light source to reset spin states in the magneto-optical defect center material to a ground state after irradiating the magneto-optical defect center material with optical excitation, wherein the reset optical light source provides a higher power light than the readout optical light source.

6. A system for magnetic detection, comprising:
a magneto-optical defect center material comprising a plurality of magneto-optical defect centers;
a radio frequency (RF) excitation source configured to provide RF excitation to the magneto-optical defect center material;
an optical detector configured to receive an optical signal emitted by the magneto-optical defect center material; and
an optical light source configured to provide optical light to the magneto-optical defect center material, the optical light source comprising:
a readout optical light source configured to illuminate light in a first illumination volume of the magneto-optical defect center material; and
a reset optical light source configured to illuminate light in a second illumination volume of the magneto-optical defect center material, the second illumination volume being larger than and encompassing the first illumination volume.

7. The system of claim 6, wherein the readout optical light source is a laser and the reset optical light source is a bank of LED flash-bulbs.

8. The system of claim 6, wherein the readout optical light source is an LED and the reset optical light source is a bank of LED flash-bulbs.

9. The system of claim 6, wherein the readout optical light source has a higher duty cycle than the reset optical light source.
